(19) United States
(12) Patent Application Publication
(10) Pub. No.: US 2006/0284306 A1
(43) Pub. Date: Dec. 21, 2006

(54) Multi-chip type semiconductor device

(76) Inventor: Hideo Taniuchi, OSAKA (JP)

Correspondence Address: STEPTOE & JOHNSON LLP, 1330 CONNECTICUT AVE., NW, WASHINGTON, DC, 20036, US

(21) Appl. No.: 10/568,620

(22) PCT Filed: Aug. 2, 2004
(86) PCT No.: PCT/JP04/11395

§ 371 Date: Feb. 16, 2006

(30) Foreign Application Priority Data
Nov. 27, 2003 (JP) 2003-397103

(51) Int. Cl. H01L 23/34

(52) U.S. Cl. 257/723

(57) ABSTRACT

A first semiconductor chip (1) of a high withstand voltage and a second semiconductor chip (2) of a low withstand voltage are connected to each other in a package (3). The first semiconductor chip (1) has a voltage conversion circuit (4), a plurality of first inter-chip connection portions (10) for connection to the second semiconductor chip (2), a first serial decoder (6), and external connection portions (13) for connection to the external connection terminals (12) led out of the package (3). The second semiconductor chip (2) has a second serial decoder (5) and a plurality of second inter-chip connection portions (11) for connection to the first semiconductor chip (1). Bonding wires (9) are provided which directly connect the plurality of first inter-chip connection portions (10) and the plurality of second inter-chip connection portions (11) to each other.

### TECHNICAL FIELD

The present invention relates to a multi-chip-type semiconductor device having a plurality of semiconductor chips packed in one package.

### BACKGROUND ART

In a multi-chip-type semiconductor device in which a plurality of semiconductor chips are connected and resin-molded, connections between the semiconductor chips are made in various forms. For example, connections between the semiconductor chips may be made by means of a bonding wire. The semiconductor chips may be superposed one on another in a chip-on-chip structure and electrical connections between the semiconductor chips may be made by means of bumps. Further, electrical connections between the plurality of semiconductor chips may be established by joining the semiconductor chips together on a wiring substrate.

The reason for packing a plurality of chips in one package is that, for example, in the case of LSI with a need for high-frequency signal processing and low-frequency-based processing, frequency characteristics high enough for high-frequency signal processing cannot be obtained if integration in one chip is performed by using a process for low-frequency use, and an increase in cost results if integration in one chip is performed by using a process for high-frequency use. In such a case, semiconductor chips may have different withstand voltages and there are various problems to be solved.

For example, a technique described in Japanese Patent Laid-Open No. 2000-332193 is a solution to a problem in testing the operation of a multi-chip-type semiconductor having chips of different withstand voltages packed in one package.

A solution to a problem relating to serial data transmission will be described with reference to FIG. 6.

FIG. 6 is a block diagram showing the configuration of a conventional multi-chip-type semiconductor device having chips of different withstand voltages packed in one package, i.e., a multi-chip-type semiconductor device having a first semiconductor chip 1 and a second semiconductor chip 2 packed in a package 3. The first semiconductor chip 1 has a first serial decoder 6 and external connection portions 13, while the second semiconductor chip 2 has a second serial decoder 5 and external connection portions 23.

A voltage source 7 is connected to a microcomputer 8 and to the first semiconductor chip 1. A group of serial data supplied from the microcomputer 8 is supplied to the first semiconductor chip 1 via serial data external connection terminals 12. The voltage of another group of serial data supplied from the microcomputer 8 is reduced by a voltage conversion circuit 21 and the data is thereafter supplied to the second semiconductor chip 2 via serial data external connection terminals 22.

The groups of serial data supplied from the microcomputer 8 are output to the first semiconductor chip 1 and the second semiconductor chip 2 in parallel with each other to control circuits in the first and second semiconductor chips 1 and 2.

The first semiconductor chip 1 is a high-withstand-voltage chip, while the second semiconductor chip 2 is a low-withstand-voltage chip. The withstand voltage value of the low-withstand-voltage chip is equal to or lower than the voltage value of the serial data supplied from the microcomputer 8.

In the serial transmission system of the conventional multi-chip-type semiconductor device shown in FIG. 6, however, serial data external connection terminals 22 are required to externally supply the serial data to the low-withstand-voltage chip. The number of pins and, hence, the mount area, is increased and it is difficult to reduce the overall size of the package. Moreover, there is a need for the external voltage conversion circuit 21 and an increase in cost results.

The present invention has been achieved in consideration of the problem of the conventional art, and an object of the present invention is to provide a multi-chip-type semiconductor device capable of transmitting serial data while having such a configuration that the number of external connection terminals is not largely increased and there is no need for an external voltage conversion circuit.

### DISCLOSURE OF THE INVENTION

The first invention in the present invention provided to achieve the above-described object relates to a multi-chip-type semiconductor device including a first semiconductor chip and a second semiconductor chip connected to each other in a package and has features described below. The first semiconductor chip has a voltage conversion circuit, a plurality of first inter-chip connection portions for connection to the second semiconductor chip, a first serial decoder, external connection terminals led out of the package, and external connection portions for connection to the external connection terminals. The second semiconductor chip has a second serial decoder and a plurality of second inter-chip connection portions for connection to the first semiconductor chip. Bonding wires are also provided which directly connect the plurality of first inter-chip connection portions and the plurality of second inter-chip connection portions to each other. The semiconductor device is thus configured and serial data input through the external connection terminals is transmitted to the second serial decoder via the voltage conversion circuit, the first inter-chip connection portions and the second inter-chip connection portions.

The second invention in the present invention relates to a multi-chip-type semiconductor device including a first semiconductor chip and a second semiconductor chip connected to each other in a package and has features described below. The first semiconductor chip has a voltage conversion circuit, a plurality of first inter-chip connection portions for connection to the second semiconductor chip, a first internal circuit, external connection terminals led out of the package, and external connection portions for connection to the external connection terminals. The second semiconductor chip has a second internal circuit and a plurality of second inter-chip connection portions for connection to the first semiconductor chip. Bonding wires are also provided which directly connect the plurality of first inter-chip connection portions and the plurality of second inter-chip connection portions to each other. The semiconductor device is thus configured and a control signal input through the external connection terminals is transmitted to the second internal circuit via the voltage conversion circuit, the first inter-chip connection portions and the second inter-chip connection portions.

In the present invention, a high voltage can be applied to the first semiconductor chip, and the second semiconductor chip can have a withstand voltage lower than that of the first semiconductor chip and lower that the voltage of the serial data externally applied.

Also, the first semiconductor chip and the second semiconductor chip can be made controllable by serial data from a microcomputer.

These arrangements enable transmission of serial data and transmission of a control signal without directly applying a high voltage to the low-withstand-voltage chip.

According to the present invention, transmission of serial data and transmission of a control signal can be performed without directly applying a high voltage to the low-withstand-voltage chip, as described above. Thus, the provision of a multi-chip-type semiconductor device capable of transmitting serial data while having such a configuration that the number of external connection terminals is not largely increased and there is no need for an external voltage conversion circuit is achieved.

### BRIEF DESCRIPTION OF THE DRAWINGS

FIG. 1 is a block diagram showing the configuration of a multi-chip-type semiconductor device in Embodiment 1 of the present invention;

FIG. 2 is a block diagram showing the configuration of a multi-chip-type semiconductor device in Embodiment 2 of the present invention;

FIG. 3 is a circuit diagram showing an example of a voltage conversion circuit of the present invention;

FIG. 4 is a block diagram showing the configuration of a multi-chip-type semiconductor device in Embodiment 3 of the present invention;

FIG. 5 is a circuit diagram showing an example of a second serial decoder input circuit in Embodiment 3 of the present invention; and

FIG. 6 is a block diagram showing a conventional multi-chip-type semiconductor device.

### BEST MODE FOR CARRYING OUT THE INVENTION

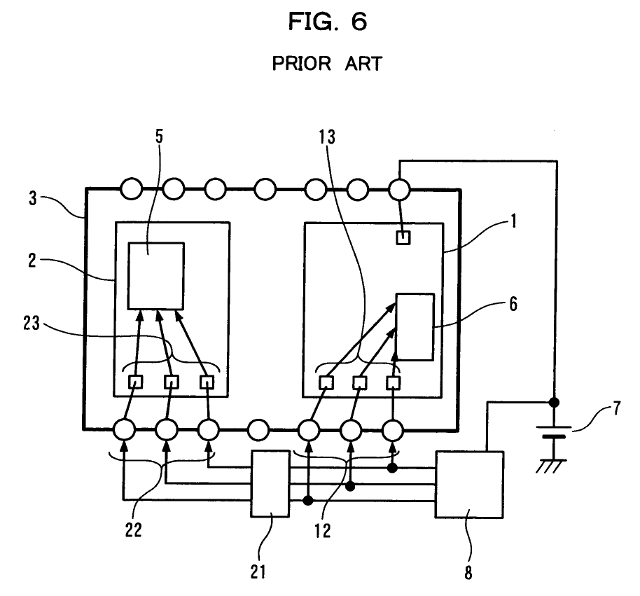

Embodiments of the present invention will be described with reference to the drawings. In the following description, components corresponding to those described with reference to FIG. 6 are indicated by the same reference numerals.

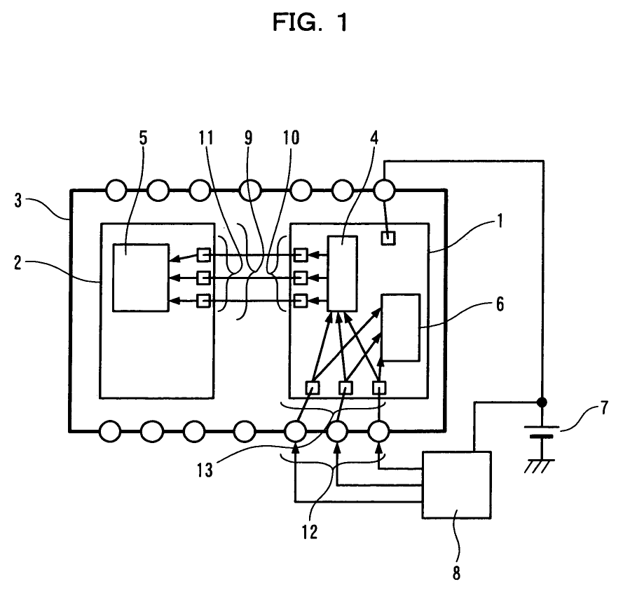

FIG. 1 is a block diagram showing the configuration of a multi-chip-type semiconductor device in Embodiment 1 of the present invention. A first semiconductor chip 1 of a high withstand voltage and a second semiconductor chip 2 of a low withstand voltage are connected to each other in a package 3.

The first semiconductor chip 1 has a voltage conversion circuit 4, a plurality of first inter-chip connection portions 10 for connection to the second semiconductor chip 2, a first serial decoder 6, and external connection portions 13 for connection to external connection terminals 12 led out of the package 3. The second semiconductor chip 2 has a second serial decoder 5 and a plurality of second inter-chip connection portions 11 for connection to the first semiconductor chip 1.

Further, bonding wires 9 are provided which directly connect the plurality of first inter-chip connection portions 10 and the plurality of second inter-chip connection portions 11 to each other. The voltage of serial data input through the external connection terminals 12 is reduced by the voltage conversion circuit 4 and the serial data is then supplied to the second serial decoder 5 via the first inter-chip connection portions 10 and the second inter-chip connection portions 11.

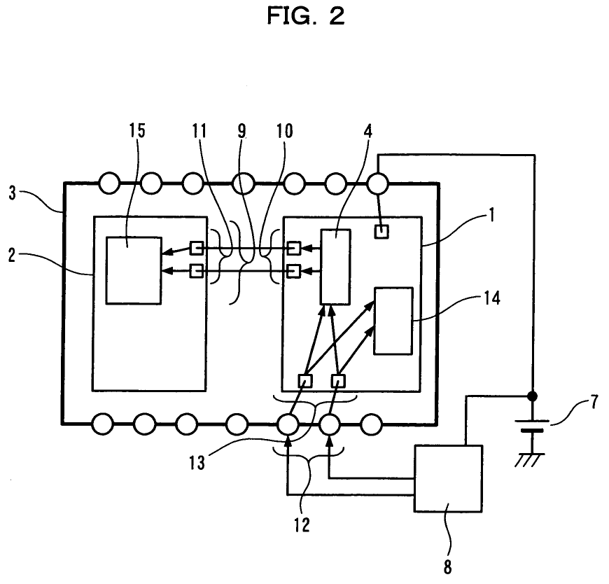

FIG. 2 is a block diagram showing the configuration of a multi-chip-type semiconductor device in Embodiment 2 of the present invention. A first semiconductor chip 1 has a voltage conversion circuit 4, a plurality of first inter-chip connection portions 10 for connection to the second semiconductor chip 2, a first internal circuit 14, external connection terminals 12 led out of the package 3, and external connection portions 13 for connection to the external connection terminals 12. The second semiconductor chip 2 has a second internal circuit 15 and a plurality of second inter-chip connection portions 11 for connection to the first semiconductor chip 1.

Further, bonding wires 9 are provided which directly connect the plurality of first inter-chip connection portions 10 and the plurality of second inter-chip connection portions 11. The voltage of a control signal input through the external connection terminals 12 is reduced by the voltage conversion circuit 4 and the control signal is then supplied to the second internal circuit 15 via the first inter-chip connection portions 10 and the second inter-chip connection portions 11.

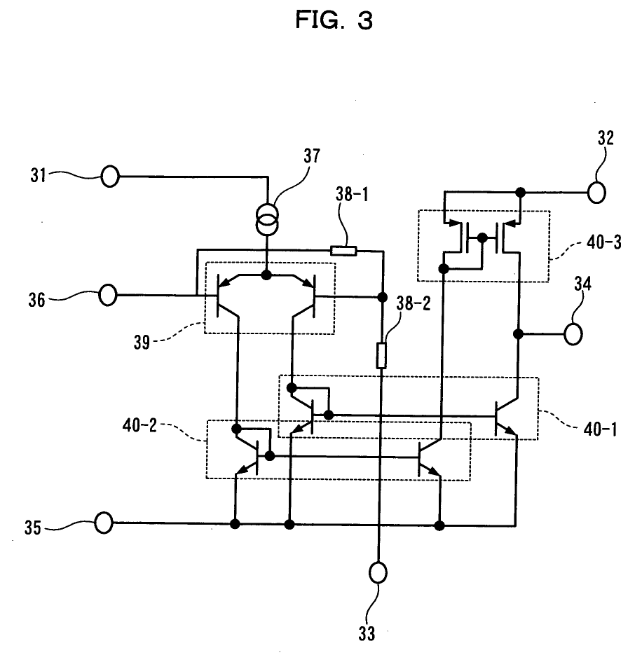

FIG. 3 is a circuit diagram showing an example of the voltage conversion circuit 4 in this embodiment having a power supply voltage terminal 31, a low-withstand-voltage power supply terminal 32, a serial data input terminal 33, an output terminal 34, a GND terminal 35, a reference voltage terminal 36, a constant-current source 37, resistors 38-1 and 38-2, a PNP differential pair transistors (Tr) 39, and current mirror circuits 40-1 to 40-3.

The power supply voltage terminal 31 is connected to a power supply 7; the low-withstand-voltage power supply terminal 32 to a power supply voltage set equal to or lower than the withstand voltage of the low-withstand-voltage chip; the serial data input terminal 33 to the serial data external connection terminal 12; and the output terminal 34 to the first inter-chip connection portion 10.

The same amplitude of voltage as that of the power supply 7 is input to the serial data input terminal 33. One of the PNP differential pair transistors 39 is turned on or off depending on whether this amplitude of voltage is higher or lower than a voltage applied to the reference voltage terminal 36. Simultaneously, one of the current mirror circuits 40-1 and 40-2 is turned on or off. A serial data signal having the same amplitude value as the power supply voltage applied to the low-withstand-voltage power supply terminal 32 is finally obtained.

The above-described arrangement is capable of transmitting serial data and a control signal without directly applying a high voltage to the low-withstand-voltage second semiconductor chip 2.

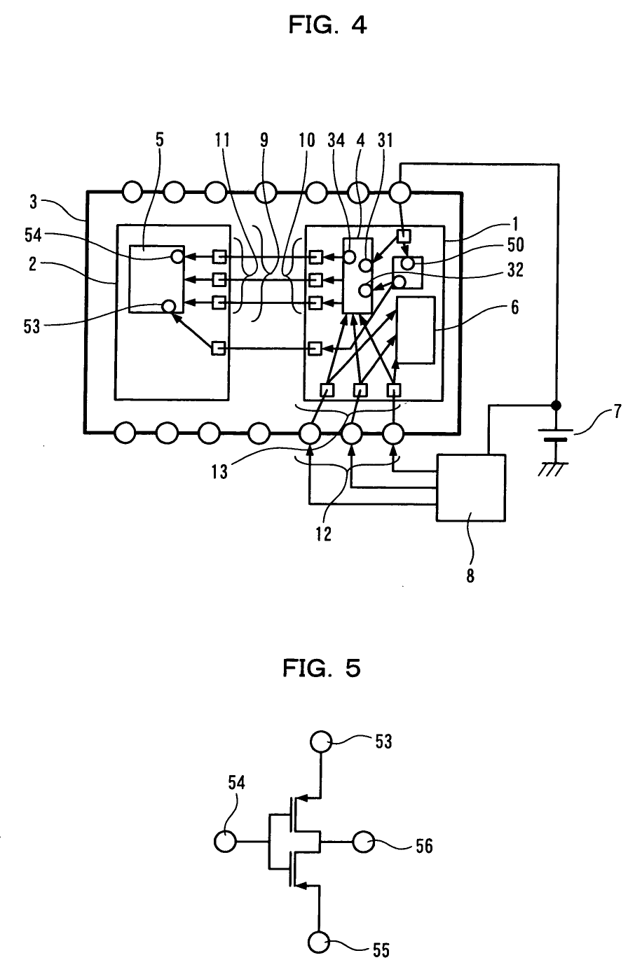

FIG. 4 is a block diagram showing the configuration of a multi-chip-type semiconductor device in Embodiment 3 of the present invention. A high-withstand-voltage chip 1 has a withstand voltage of 10 V and a power supply changes to 7 V at the maximum. A low-withstand-voltage chip 2 has a withstand voltage of 3.6 V.

The power supply 7 is connected to a power supply 31 for a voltage conversion circuit 4 and to a power supply terminal of a 3 V regulator 50. An output of the 3 V regulator 50 is connected to a power supply terminal 53 of an input circuit of a second serial decoder 5 via an output-side power supply 32 of the voltage conversion circuit 4, bonding wires 9, a plurality of first inter-chip connection portions 10 and a plurality of second inter-chip connection portions 11.

Output terminals 34 of the voltage conversion circuit 4 are connected to input terminals 54 of the input circuit of the second serial decoder 5 via the bonding wires 9, the plurality of inter-chip connection portions 10 and the plurality of second inter-chip connection portions 11.

FIG. 5 shows the input circuit of the second serial decoder 5 having the input terminal 54, an output terminal 56 connected to a circuit in a following stage, the power supply terminal 53 and a ground terminal 55.

In the above-described arrangement, serial data having an amplitude of 7 V at the maximum is voltage-converted into serial data the amplitude of which is limited to 3 V, which is supplied to the low-withstand-voltage chip 2 without exceeding the withstand voltage of the low-withstand-voltage chip 2.

### INDUSTRIAL APPLICATION

The present invention is applied to a multi-chip-type semiconductor device having a plurality of semiconductor chips packed in one package and is implemented particularly effectively as a multi-chip-type semiconductor device capable of transmitting serial data while having such a configuration that the number of external connection terminals is not largely increased and there is no need for an external voltage conversion circuit.

1. A multi-chip-type semiconductor device comprising a first semiconductor chip and a second semiconductor chip connected to each other in a package, wherein
said first semiconductor chip comprises a voltage conversion circuit, a plurality of first inter-chip connection portions for connection to the second semiconductor chip, a first serial decoder, external connection terminals led out of the package, and external connection portions for connection to the external connection terminals,
said second semiconductor chip comprises a second serial decoder and a plurality of second inter-chip connection portions for connection to the first semiconductor chip,
bonding wires are provided, for directly connecting the plurality of first inter-chip connection portions and the plurality of second inter-chip connection portions to each other, and
serial data input through the external connection terminals is transmitted to the second serial decoder via the voltage conversion circuit, the first inter-chip connection portions and the second inter-chip connection portions.

2. The multi-chip-type semiconductor device according to claim 1, wherein a high voltage can be applied to the first semiconductor chip, and the second semiconductor chip has a withstand voltage lower than that of the first semiconductor chip and lower than the voltage of the serial data externally applied.

3. The multi-chip-type semiconductor device according to claim 1, wherein the first semiconductor chip and the second semiconductor chip are controlled by serial data from a microcomputer.

4. A multi-chip-type semiconductor device comprising a first semiconductor chip and a second semiconductor chip connected to each other in a package, wherein
said first semiconductor chip comprises a voltage conversion circuit, a plurality of first inter-chip connection portions for connection to the second semiconductor chip, a first serial decoder, external connection terminals led out of the package, and external connection portions for connection to the external connection terminals,
said second semiconductor chip comprises a second internal circuit and a plurality of second inter-chip connection portions for connection to the first semiconductor chip,
bonding wires are provided for directly connecting the plurality of first inter-chip connection portions and the plurality of second inter-chip connection portions to each other, and
a control signal input through the external connection terminals is transmitted to the second internal circuit via the voltage conversion circuit, the first inter-chip connection portions and the second inter-chip connection portions.

5. The multi-chip-type semiconductor device according to claim 4, wherein a high voltage can be applied to the first semiconductor chip, and the second semiconductor chip has a withstand voltage lower than that of the first semiconductor chip and lower than the voltage of the control signal externally applied.

6. The multi-chip-type semiconductor device according to claim 4, wherein the first semiconductor chip and the second semiconductor chip are controlled by control signal from a microcomputer.
